(19) United States
(12) Patent Application Publication
(10) Pub. No.: US 2025/0347719 A1
(43) Pub. Date: Nov. 13, 2025

(54) CURRENT AND VOLTAGE METERING BUSHING

(71) Applicant: LINDSEY MANUFACTURING CO., Azusa, CA (US)

(72) Inventors: Daniel H. Lee, Fullerton, CA (US); Christopher J. Meeks, Azusa, CA (US); Robert May, Azusa, CA (US); Keith E. Lindsey, La Canada, CA (US); An-Chyun Wang, Cerritos, CA (US); Keith M. Carpenter, Buena Park, CA (US)

(21) Appl. No.: 19/201,833

(22) Filed: May 7, 2025

Related U.S. Application Data
(60) Provisional application No. 63/643,907, filed on May 7, 2024.

(51) Int. Cl. G01R 15/14; G01D 21/02; G01R 15/04; G01R 15/18

(52) U.S. Cl. CPC G01R 15/142; G01D 21/02; G01R 15/04; G01R 15/181; G01R 15/183

(57) ABSTRACT

A current and voltage measuring bushing is disclosed. The current and voltage measuring bushing may have a current sensor and a resistive voltage divider commonly located in the bushing. In one or more embodiments, the current and voltage metering bushing may have current and voltage measuring accuracy of 0.3% or better.

### CROSS-REFERENCE TO RELATED APPLICATION

The present application claims the benefit of U.S. Provisional Application No. 63/643,907, filed on May 7, 2024, the entire disclosure of which is incorporated herein by reference.

### BACKGROUND

### 1. Field

Aspects of embodiments of the present invention relate to a current and voltage measuring bushing.

### 2. Description of the Related Art

A bushing may be provided consisting of a conductive electrode passing through a housing to provide an electrical connection from one side of the housing to the other, insulating the electrode from the surface through which the bushing housing is installed. A typical application is where the bushing is placed in a hole through a metal cabinet wall forming part of an electrical switchgear cabinet where the bushing housing allows the connection to pass through the cabinet wall as shown in FIG. 9. However, a current transformer, current sensor, voltage transformer, or voltage sensor may be separate from and wired to the bushing or before or after the bushing in order to measure the current flowing through the bushing and the voltage potential between the electrode and the surface through which the busing is installed.

### SUMMARY

According to an aspect of one or more embodiments of the present invention, a current and voltage measuring bushing having a current sensor or transformer and a voltage sensor or transformer commonly located in the bushing is provided, such that a separate current transformer or current sensor and a voltage sensor or voltage transformer is not needed.

According to another aspect of one or more embodiments of the present invention, a current and voltage measuring bushing having current and voltage measuring accuracy of 0.3% or better (e.g., revenue-class metering accuracy) is provided.

According to another aspect of one or more embodiments of the present invention, a current and voltage measuring bushing meeting the dimensional and electrical requirements of IEEE Standard 386 is provided.

According to another aspect of one or more embodiments of the present invention, a current and voltage measuring bushing meeting the dimensional and electrical requirements of IEC Standard 60502-4 and/or IEC Standard 61442 is provided.

### BRIEF DESCRIPTION OF THE DRAWINGS

The above and other features and aspects will become more apparent to those of ordinary skill in the art by describing in further detail some example embodiments of the present invention with reference to the attached drawings, in which:

FIG. 1 is a perspective view of a current and voltage measuring bushing according to an embodiment of the present invention;

FIG. 2 is a front view of the current and voltage measuring bushing of FIG. 1;

FIG. 3 is a rear view of the current and voltage measuring bushing of FIG. 1;

FIG. 4 is a side view of the current and voltage measuring bushing of FIG. 1;

FIG. 5 is an opposite side view of the current and voltage measuring bushing of FIG. 1;

FIG. 6 is a top view of the current and voltage measuring bushing of FIG. 1;

FIG. 7 is a bottom view of the current and voltage measuring bushing of FIG. 1;

FIG. 8 is a perspective view of the current and voltage measuring bushing of FIG. 1 showing an interior thereof; and

FIG. 9 is a view of a conventional bushing.

### DETAILED DESCRIPTION

Herein, some example embodiments will be described in further detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and, thus, descriptions thereof may not be repeated.

In the drawings, relative sizes of elements, layers, and regions may be exaggerated and/or simplified for clarity.

It is to be understood that, although the terms “first,” “second,” “third,” etc., may be used herein to describe various elements, components, regions, layers and/or sections, these elements, components, regions, layers, and/or sections are not limited by these terms. These terms are used to distinguish one element, component, region, layer or section from another element, component, region, layer, or section. Thus, a first element, component, region, layer, or section described below could be termed a second element, component, region, layer, or section, without departing from the spirit and scope of the present disclosure.

It is to be understood that when an element or layer is referred to as being “on,” “connected to,” or “coupled to” another element or layer, it may be directly on, connected to, or coupled to the other element or layer, or one or more intervening elements or layers may be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It is to be further understood that the terms “comprises,” “comprising,” “includes,” and “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless otherwise defined, all terms (including technical and scientific terms) used herein have the same meaning as commonly understood by one of ordinary skill in the art to which the present disclosure belongs. It is to be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

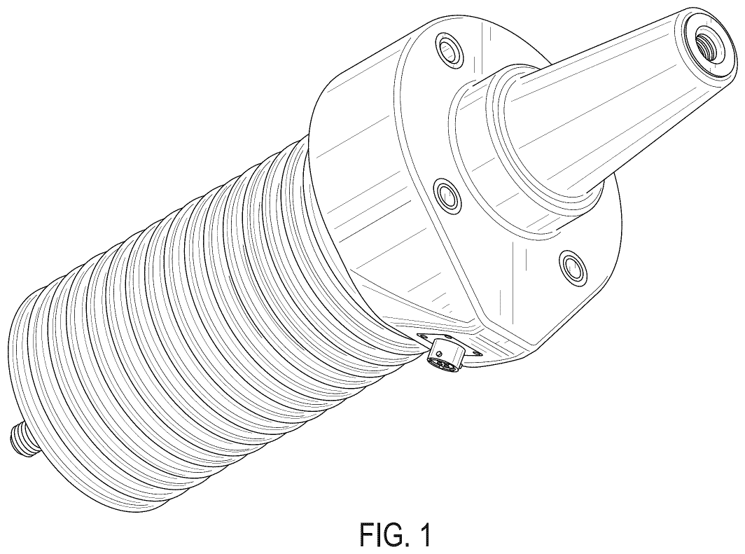

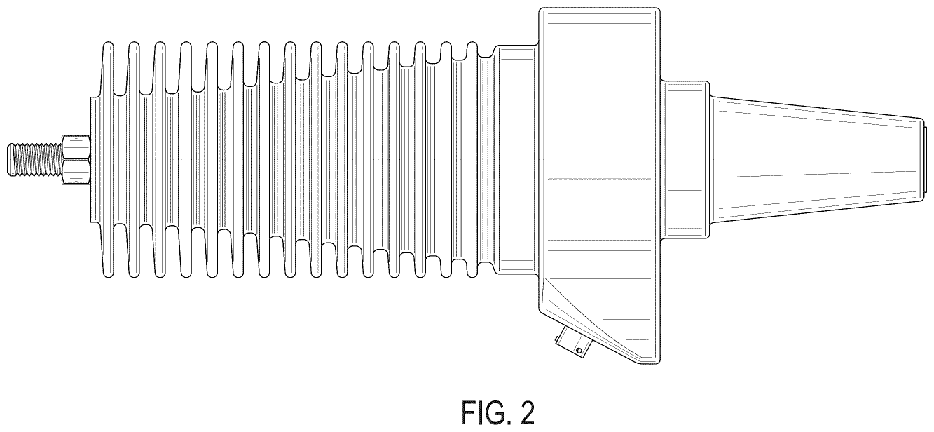

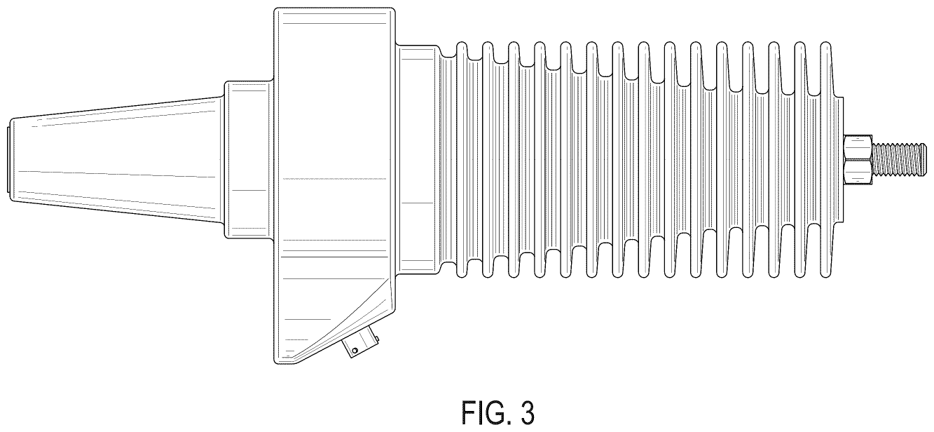

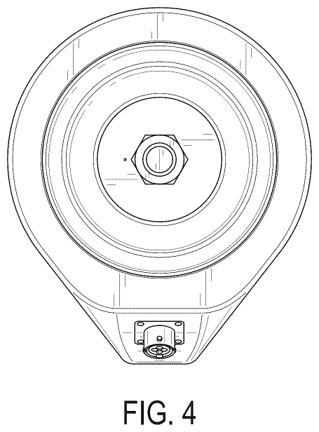

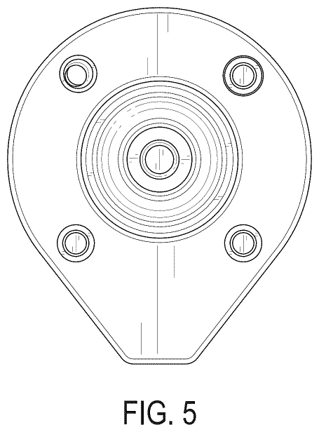

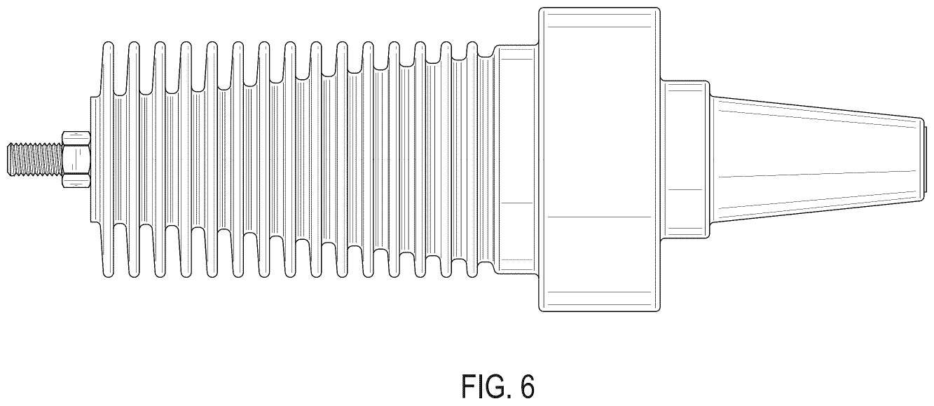

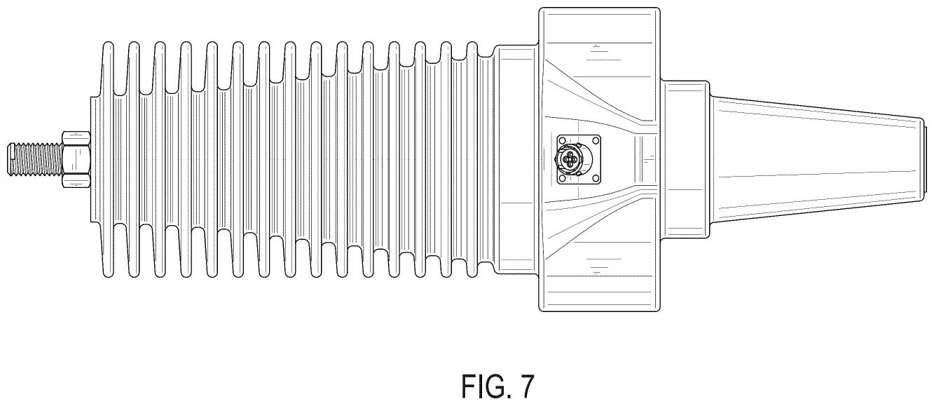

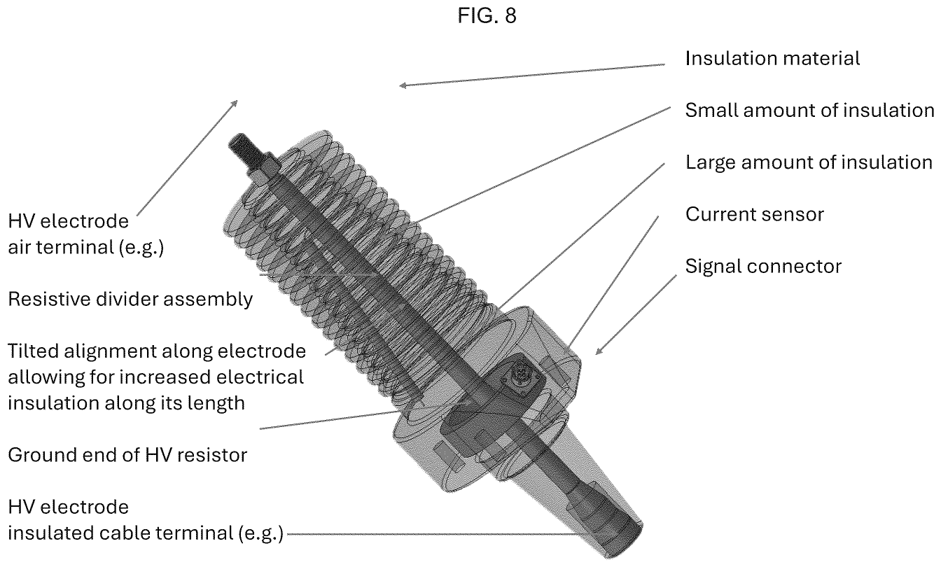

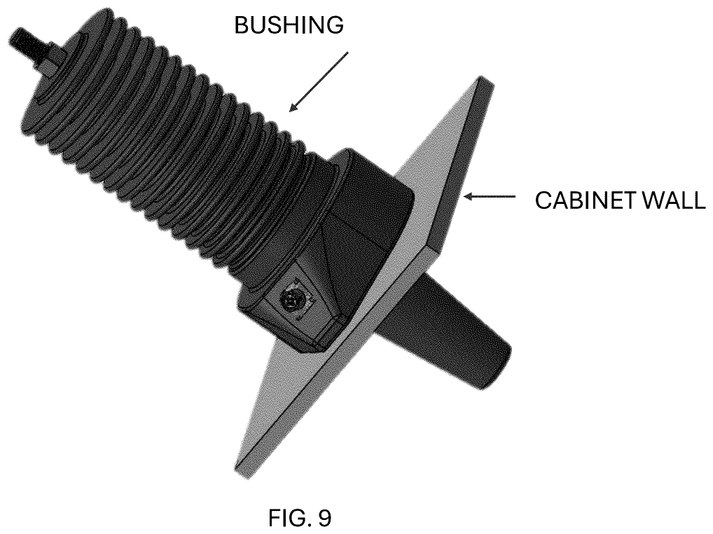

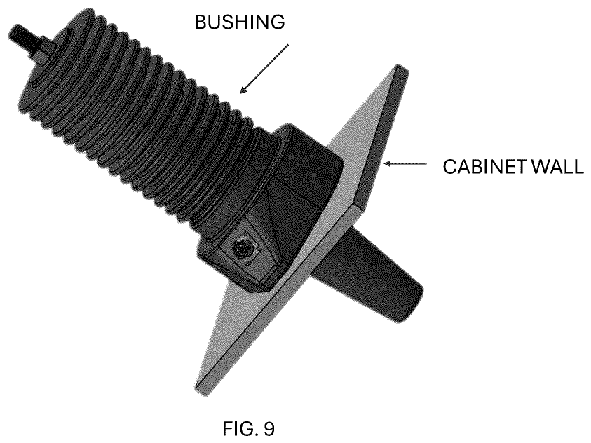

Embodiments of the present invention provide a current and voltage measuring bushing. FIG. 1 is a perspective view of a current and voltage measuring bushing according to an embodiment of the present invention; FIG. 2 is a front view of the current and voltage measuring bushing of FIG. 1; FIG. 3 is a rear view of the current and voltage measuring bushing of FIG. 1; FIG. 4 is a side view of the current and voltage measuring bushing of FIG. 1; FIG. 5 is an opposite side view of the current and voltage measuring bushing of FIG. 1; FIG. 6 is a top view of the current and voltage measuring bushing of FIG. 1; FIG. 7 is a bottom view of the current and voltage measuring bushing of FIG. 1; and FIG. 8 is a perspective view of the current and voltage measuring bushing of FIG. 1 showing an interior thereof.

As shown in the drawings, a current and voltage measuring bushing according to one or more embodiments of the present invention includes a high-voltage (HV) electrode, a high-voltage (HV) resistor, an insulation material around (e.g., surrounding) the HV electrode and the HV resistor, a current transformer (CT), a low voltage (LV) resistor, a signal connector, and mounting bolt bosses.

In one or more embodiments, the current and voltage measuring bushing has a cylindrical shape, and may have a 200 or 600 Ampere rating, for example.

In one or more embodiments of the present invention, the current and voltage measuring bushing includes a resistive potential divider, which differs from a capacitive divider, and does not need to condition a signal any further. In another embodiment, the current and voltage bushing includes a Rogowski coil arranged around an electrode running longitudinally along a center of the bushing in addition to the resistive potential divider, where the Rogowski coil may be provided in a form requiring its output to be conditioned further, or in an embodiment where the output conditioning may be performed within the housing of the bushing. In one or more embodiments of the present invention, the current and voltage metering bushing has a magnetic core current transformer (CT) arranged around an electrode running longitudinally along a center of the bushing. The current transformer may be a wound current transformer with a resistive potential divider, rather than a capacitive potential divider, and a signal thereof does not need to be conditioned further.

The current and voltage measuring bushing includes an insulative material, such as an epoxy (e.g., hydrophobic cycloaliphatic epoxy) or a polymer concrete material, around (e.g., surrounding) an electrode. A lower end of the electrode may connect to an insulated cable terminal, for example, outside of a housing through which the bushing passes. An upper end of the electrode may include an air insulator.

Additionally, in one or more embodiments of the present invention, the current and voltage metering bushing includes a high-voltage resistor (see FIG. 8) arranged at an angle (or tilted) with respect to a longitudinal axis of the electrode. As such, more electrical insulation may be provided at a lower portion of the high-voltage resistor than at an upper portion thereof. That is, due to the tilted alignment of the high-voltage resistor, increased electrical insulation may be provided along a length thereof. For example, a lower portion of the high-voltage resistor may be near ground potential. The high-voltage resistor may be connected between the high-voltage electrode at a top thereof and a low-voltage resistor at a bottom thereof. Additionally, in one or more embodiments of the present invention, the current and voltage metering bushing includes a high-voltage resistor (see FIG. 8) arranged in parallel to the longitudinal axis of the electrode. As such, a graded dielectric material may be used between the electrode and the resistor to provide more electrical insulation at a lower portion (i.e., low voltage end) of the high-voltage resistor than at an upper portion thereof. That is, due to the grading of the dielectric material, increased electrical insulation may be provided along a length thereof. For example, a lower portion of the high-voltage resistor may be near ground potential. The high-voltage resistor may be connected between the high-voltage electrode at a top thereof and a low-voltage resistor at a bottom thereof.

The signal connector (see FIG. 8) may be a suitable connector for bringing out the voltage/current signals. In an embodiment, the connector may be a bayonet type connector, or a multipin or screw connector, or a modular connector similar to RJ45 connectors used in computer networking equipment, for example. Additionally, in one or more embodiments of the present invention, other sensors that may provide meaningful information as to the condition or performance of the bushing or the bushing's environment, e.g., temperature, pressure, radiation, moisture, thermal radiation, arcing, smoke, gaseous components, etc., may also be included in the bushing and whose outputs may be brought out through the same or a separate signal connector. Additionally, in one or more embodiments of the present invention, embedded sensors that may require further conditioning, e.g., Rogowski coil outputs, may have their conditioning circuitry contained within the bushing, where power for conditioning circuitry may be provided externally to the bushing, e.g., from power-over-Ethernet (POE) connectors.

Although some example embodiments have been described herein, those skilled in the art will readily appreciate that various modifications are possible in the example embodiments without departing from the spirit and scope of the present disclosure. It is to be understood that descriptions of features or aspects within each embodiment should typically be considered as available for other similar features or aspects in other embodiments, unless otherwise described. Therefore, it is to be understood that the foregoing is illustrative of various example embodiments and is not to be construed as limited to the specific example embodiments disclosed herein, and that various modifications to the disclosed example embodiments, as well as other example embodiments, are intended to be included within the spirit and scope of the present disclosure as set forth in the appended claims, and their equivalents.

What is claimed is:

1. A current and voltage measuring bushing comprising a resistive divider that is slanted to provide insulation strength at a low voltage terminal.

2. The current and voltage measuring bushing of claim 1, wherein a dielectric strength of a bushing material is graded to provide insulation strength at a low voltage terminal.

3. The current and voltage measuring bushing of claim 1, further comprising a voltage sensing element that is a resistive voltage divider, and a current sensing element that is an iron core CT.

4. The current and voltage measuring bushing of claim 1, wherein the voltage sensing element is a resistive voltage divider and the current sensing element is a Rogowski coil wherein the signal correction circuit of the coil is external to the bushing.

5. The current and voltage measuring bushing of claim 1, wherein the voltage sensing element is a resistive voltage divider, and the current sensing element is a Rogowski coil wherein the coil's signal correction circuit is internal to the bushing.

6. The current and voltage measuring bushing of claim 1, wherein the voltage and current measurement signal are brought to a connector accessible on a surface of the bushing.

7. The current and voltage measuring bushing of claim 5, wherein the voltage sensing element is a resistive voltage divider, and the current sensing element is an iron core CT.

8. The current and voltage measuring bushing of claim 5, wherein the voltage sensing element is a resistive voltage divider, and the current sensing element is a Rogowski coil wherein the coil's signal correction circuit is external to the bushing.

9. The current and voltage measuring bushing of claim 5 wherein the voltage sensing element is a resistive voltage divider, and the current sensing element is a Rogowski coil where the coil's signal correction circuit is internal to the bushing.

10. The current and voltage measuring bushing of claim 5 wherein the voltage and current measurement signal are brought to a connector accessible on the surface of the bushing.

11. The current and voltage measuring bushing of claim 1 further comprising a temperature sensor.

12. The current and voltage measuring bushing of claim 1, further comprising a pressure sensor.

13. The current and voltage measuring bushing, further comprising a moisture sensor.

14. The current and voltage measuring bushing of claim 1, further comprising a thermal radiation sensor.

15. The current and voltage measuring bushing of claim 1, further comprising an arcing sensor.

16. The current and voltage measuring bushing of claim 1 further comprising a smoke sensor.

17. The current and voltage measuring bushing of claim 1 further comprising a gas sensor.

18. The current and voltage measuring bushing of claim 6, further comprising a temperature sensor.

19. The current and voltage measuring bushing of claim 6, further comprising a pressure sensor.

20. The current and voltage measuring bushing of claim 6, further comprising a moisture sensor.
